(19) United States
(12) Patent Application Publication
(10) Pub. No.: US 2024/0363601 A1
(43) Pub. Date: Oct. 31, 2024

(54) CHIP PACKAGE STRUCTURE AND PREPARATION METHOD THEREOF

(71) Applicant: STATS CHIPPAC SEMICONDUCTOR (JIANGYIN) CO., LTD., JIANGSU (CN)

(72) Inventors: Zelong Yu, JIANGSU (CN); Huanhuan Yuan, JIANGSU (CN); Jian Xu, JIANGSU (CN); Soo Won Lee, JIANGSU (CN)

(73) Assignee: STATS CHIPPAC SEMICONDUCTOR (JIANGYIN) CO., LTD., JIANGSU (CN)

(21) Appl. No.: 18/646,794

(22) Filed: Apr. 26, 2024

(30) Foreign Application Priority Data
Apr. 27, 2023 (CN) 202310470214.4

(51) Int. Cl. H01L 25/10; H01L 21/56; H01L 23/00; H01L 23/31; H01L 23/498; H01L 23/538; H01L 25/00

(52) U.S. Cl. CPC H01L 25/105; H01L 21/568; H01L 23/3135; H01L 23/3185; H01L 23/49811; H01L 23/5383; H01L 24/16; H01L 24/32; H01L 24/73; H01L 24/92; H01L 25/50; H01L 2224/16225; H01L 2224/32225; H01L 2224/73204; H01L 2224/92125

(57) ABSTRACT

The present disclosure discloses a chip package structure and a preparation method thereof. The chip package structure includes: a metal wiring layer; a first chip, wherein a front surface of the first chip is flip-chipped on a first surface of the metal wiring layer; a first molding layer coating the first chip; a second chip, wherein a front surface of the second chip is flip-chipped on a second surface of the metal wiring layer; a first metal pillar formed on the second surface of the metal wiring layer; a second molding layer coating the second chip and the first metal pillar; and a second metal pillar formed on one side that is of the second molding layer and that is far away from the metal wiring layer, wherein the second metal pillar is at least partially connected to the corresponding first metal pillar.

### CROSS-REFERENCE TO RELATED APPLICATION

This application claims the priority benefit of China application serial no. 202310470214.4, filed on Apr. 27, 2023. The entirety of the above-mentioned patent application is hereby incorporated by reference herein and made a part of this specification.

### TECHNICAL FIELD

The present disclosure relates to the field of semiconductors, and in particular, to a chip package structure and a preparation method thereof.

### BACKGROUND

In a fan-out package structure with a bridge chip, as shown in FIG. 12, the conventional bridge chip mounting process is as follows: a back surface that is of a bridge chip 1A and that is not thinned is thinned to obtain a thinned bridge chip 1B, then a back surface of the thinned bridge chip 1B is attached to a PI layer 1D through a die adhesive 1C. However, the disadvantage of this process is that a thickness of the bridge chip is limited. The bridge chip is too thin and is easily broken during grinding and mounting, which affects the yield of the product.

### SUMMARY

In order to solve the problems existing in the prior art, the present disclosure provides a chip package structure and a preparation method therefor, which overcomes at least one defect.

The technical solutions of the present disclosure are as follows.

A chip package structure includes:
a metal wiring layer, wherein the metal wiring layer is provided with a first surface and a second surface;
a plurality of first chips, wherein a front surface of each of the first chips is flip-chipped on the first surface of the metal wiring layer;
a first molding layer, wherein the first molding layer covers the first chip, and one side that is of the first molding layer and that is far away from the metal wiring layer is flush with a back surface of the first chip;
a second chip, wherein a front surface of the second chip is flip-chipped on the second surface of the metal wiring layer;
a first metal pillar, wherein the first metal pillar is formed on the second surface of the metal wiring layer;
a second molding layer, wherein the second molding layer covers the second chip and the first metal pillar, and one side that is of the second molding layer and that is far away from the metal wiring layer is flush with a back surface of the second chip and an end surface of the first metal pillar; and
a second metal pillar, wherein the second metal pillar is formed on one side that is of the second molding layer and that is far away from the metal wiring layer, and the second metal pillar is at least partially connected to the corresponding first metal pillar.

According to the chip package structure of the present disclosure, the first chip and the second chip are not ground before flip-chipped on the metal wiring layer, but ground after flip-chip and molding. This grinding can ensure that the thickness of the chip is as thin as possible without breaking, so that the thickness of the entire chip package structure is greatly reduced to meet the demand for thinness and convenience in the market. The extremely thin second chip (bridge chip) can reduce the design height of the first metal pillar, and thus reduce the difficulty of the process of electroplating the first metal pillar.

According to the present disclosure, the chip is flip-chipped on the metal wiring layer by various methods. In an embodiment of the present disclosure, the chip is bonded on the metal wiring layer through solder.

In some embodiments of the present disclosure, a filler is provided between the front surface of the first chip and the metal wiring layer.

In some embodiments of the present disclosure, a filler is provided between the front surface of the second chip and the metal wiring layer.

In the prior art, the reliability of a product attached to the PI layer through a die adhesive cannot be guaranteed. The second chip of the present disclosure is flip-chipped rather than front-mounted, the fixation of a wafer attach glue is canceled, and the fixation of a bottom filler is used, so that the structure of the package body is firmer, and the reliability is higher.

In some embodiments of the present disclosure, the chip package structure further includes an insulation layer, the insulation layer is positioned on one side that is of the second molding layer and that is away from the metal wiring layer, and the second metal pillar penetrates through the insulation layer.

In some embodiments of the present disclosure, the insulation layer is a PI film.

The present disclosure further discloses a preparation method for a chip package structure, which includes the following steps:
S1: preparing a carrier board, and preparing a separation layer on an upper surface of the carrier board;
S2: preparing a metal wiring layer on a surface of the separation layer;
S3: flip-chipping front surfaces of a plurality of first chips on a surface of the metal wiring layer;
S4: molding the first chip to form a first package body, wherein the first package body includes the first chip and a first molding layer covering the first chip;
S5: thinning one surface that is of the first package body and that is far away from the metal wiring layer, and thinning the first molding layer or simultaneously thinning the first molding layer and the first chip;
S6: removing the carrier board by removing the separation layer;
S7: turning over a combination of the first package body and the metal wiring layer to enable the metal wiring layer to be arranged upwards, and processing a first metal pillar connected to the metal wiring layer on the metal wiring layer;
S8: flip-chipping a front surface of a second chip on the surface of the metal wiring layer; S9: molding the second chip and the first metal pillar to form a second package body, wherein the second package body includes the second chip, the first metal pillar and a second molding layer covering the second chip and the metal pillar;
S10: thinning one surface that is of the second package body and that is far away from the metal wiring layer, thinning the second chip, the first metal pillar and the second molding layer, and exposing the first metal pillar and the second chip; and
S11: processing one surface that is of the second package body and that is far away from the metal wiring layer to obtain a second metal pillar, and processing a solder ball on an end surface of the second metal pillar, wherein the second metal pillar is at least partially connected to the corresponding first metal pillar.

According to the chip package structure of the present disclosure, the first chip and the second chip are not ground before flip-chipped on the metal wiring layer, but ground after flip-chip and molding. This grinding can ensure that the thickness of the first chip and the second chip is as thin as possible without breaking, so that the thickness of the entire chip package structure is greatly reduced to meet the demand for thinness and convenience in the market. The extremely thin second chip (bridge chip) can reduce the design height of the first metal pillar, and thus reduce the difficulty of the process of electroplating the first metal pillar.

In some embodiments, the grinding thickness of the first package body and the second package body is determined based on an actual product requirement.

In some embodiments, the first package body and the second package body are thinned by polishing and other modes.

In some embodiments of the present disclosure, the step S4, before molding the first chip, further includes providing a filler between the front surface of the first chip and the metal wiring layer.

In some embodiments of the present disclosure, the step S9, before molding the second chip and the first metal pillar, further includes providing a filler between the front surface of the second chip and the metal wiring layer.

In some embodiments of the present disclosure, the step S11 further includes processing an insulation layer on one surface that is of the second package body and that is far away from the metal wiring layer, wherein the second metal pillar penetrates through the insulation layer.

In some embodiments of the present disclosure, the insulation layer is a PI film.

The beneficial effects of the present disclosure are as follows: according to the chip package structure of the present disclosure, the first chip and the second chip are not ground before flip-chip, but ground after flip-chip and molding. This grinding can ensure that the thickness of the chip is as thin as possible without breaking, so that the thickness of the entire chip package structure is greatly reduced to meet the demand for thinness and convenience in the market. The extremely thin second chip can reduce the design height of the first metal pillar, and thus reduce the difficulty of the process of electroplating the first metal pillar.

### BRIEF DESCRIPTION OF DRAWINGS

FIG. 1 is a schematic diagram of a carrier board and a separation layer;

FIG. 2 is a schematic diagram of a surface of the separation layer of FIG. 1 after a metal wiring layer is formed thereon;

FIG. 3 is a schematic diagram of a first chip being flip-chipped on a metal wiring layer;

FIG. 4 is a schematic diagram of a first chip after being molded;

FIG. 5 is a schematic diagram of a first package body after being thinned;

FIG. 6 is a schematic diagram of FIG. 5 with a carrier board and a separation layer removed;

FIG. 7 is a schematic diagram of a combination of a first package body and a metal wiring layer being flip-chipped and then processed with a first metal pillar;

FIG. 8 is a schematic diagram of a second chip being flip-chipped on a metal wiring layer;

FIG. 9 is a schematic diagram of a second chip and a first metal pillar after being molded;

FIG. 10 is a schematic diagram of a second package body after being thinned;

FIG. 11 is a schematic diagram of a chip package structure; and

FIG. 12 is a schematic flowchart of a back surface of a conventional bridge chip being thinned and then attached to a PI layer.

### DETAILED DESCRIPTION OF EMBODIMENTS

To make objectives, technical solutions, and advantages of embodiments of the present disclosure clearer, the following clearly and completely describes technical solutions in embodiments of the present disclosure with reference to accompanying drawings in embodiments of the present disclosure. Clearly, the described embodiments are some but not all of embodiments of the present disclosure. The assemblies of embodiments of the present disclosure, as generally described and illustrated in the figures herein, can be arranged and designed in a wide variety of different configurations.

In the description of the present disclosure, it should be noted that an orientation or position relationship indicated by terms “inner”, “outer” or the like is an orientation or position relationship based on the accompanying drawings, or an orientation or position relationship that the product of the present disclosure is usually placed when in use. These terms are merely used to facilitate and simplify description of the present disclosure, instead of indicating or implying that a mentioned apparatus or element must have a specific orientation or be constructed and operated in a specific orientation, and therefore the terms cannot be construed as a limitation on the present disclosure. In addition, the terms “first”, “second”, and the like are merely intended for differentiated description, and should not be construed as an indication or an implication of relative importance.

In descriptions of the present disclosure, it should be further noted that, unless otherwise specified and limited, the terms “dispose” and “connect” should be understood in a broad sense. For example, a “connection” may be a fixed connection, a detachable connection, or an integrated connection; or may be a direct connection, an indirect connection through an intermediate medium, or an internal connection between two components. Those of ordinary skill in the art may understand specific meanings of the foregoing terms in the present disclosure based on a specific situation.

The following describes in detail embodiments of the present disclosure with reference to accompanying drawings.

As shown in FIG. 11, a chip package structure includes:
a metal wiring layer 3, wherein the metal wiring layer 3 is provided with a first surface and a second surface;
a plurality of first chips 4, wherein a front surface of each of the first chips 4 is flip-chipped on the first surface of the metal wiring layer 3;
a first molding layer 5, wherein the first molding layer 5 covers the first chip 4, and one side that is of the first molding layer 5 and that is far away from the metal wiring layer 3 is flush with a back surface of the first chip 4;
a second chip 7, wherein a front surface of the second chip 7 is flip-chipped on the second surface of the metal wiring layer 3;
a first metal pillar 6, wherein the first metal pillar 6 is formed on the second surface of the metal wiring layer 3;
a second molding layer 8, wherein the second molding layer 8 covers the second chip 7 and the first metal pillar 6, and one side that is of the second molding layer 8 and that is far away from the metal wiring layer 3 is flush with a back surface of the second chip 7 and an end surface of the first metal pillar 6; and
a second metal pillar 9, wherein the second metal pillar 9 is formed on one side that is of the second molding layer 8 and that is far away from the metal wiring layer 3, and the second metal pillar 9 is at least partially connected to the corresponding first metal pillar 6.

According to the chip package structure of the present disclosure, the first chip 4 and the second chip 7 are not ground before flip-chipped on the metal wiring layer 3, but ground after flip-chip and molding. This grinding can ensure that the thickness of the chip is as thin as possible without breaking, so that the thickness of the entire chip package structure is greatly reduced to meet the demand for thinness and convenience in the market. The second chip 7 is used as a bridge chip for bridging a plurality of first chips 4. The extremely thin second chip 7 can reduce the design height of the first metal pillar 6, and thus reduce the difficulty of the process of electroplating the first metal pillar 6.

According to the present disclosure, the chip is flip-chipped on the metal wiring layer 3 by various methods. In an embodiment of the present disclosure, the chip is bonded on the metal wiring layer 3 through solder.

As shown in FIG. 11, in this embodiment, a filler 11 is provided between the front surface of the first chip 4 and the metal wiring layer 3. A filler 11 is provided between the front surface of the second chip 7 and the metal wiring layer 3. In the prior art, the reliability of a product attached to the PI layer through a die adhesive cannot be guaranteed. The second chip 7 of the present disclosure is flip-chipped rather than front-mounted, the fixation of a wafer attach glue is canceled, and the fixation of a bottom filler 11 is used, so that the structure of the package body is firmer, and the reliability is higher.

As shown in FIG. 11, the chip package structure further includes an insulation layer 12, the insulation layer 12 is positioned on one side that is of the second molding layer 8 and that is away from the metal wiring layer 3, and the second metal pillar 9 penetrates through the insulation layer 12. In this embodiment, the insulation layer 12 is a PI film.

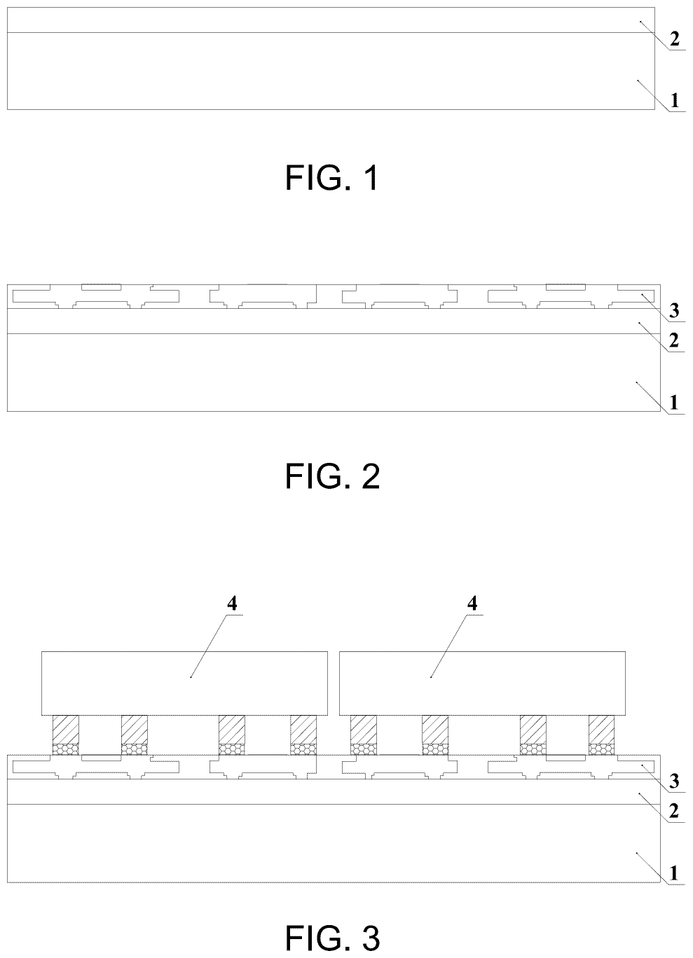

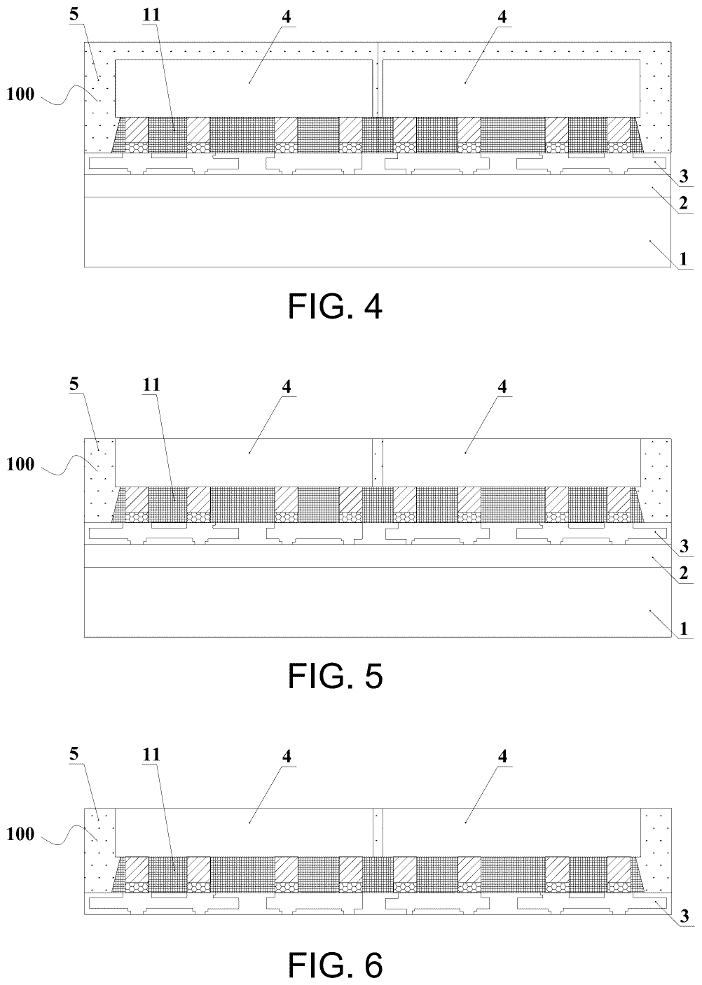

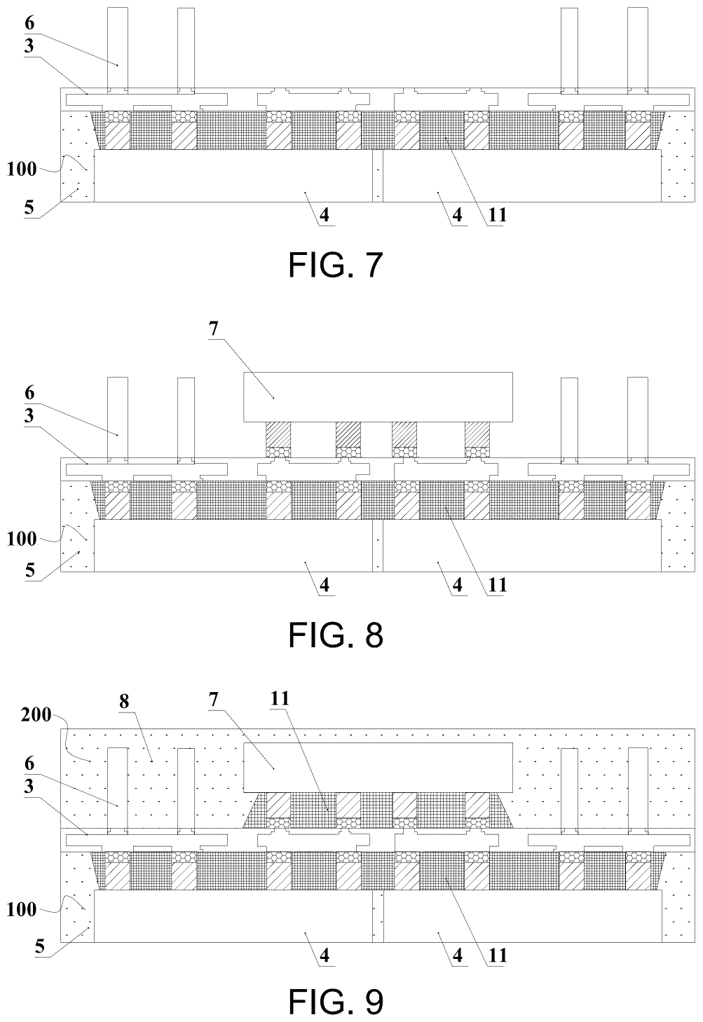

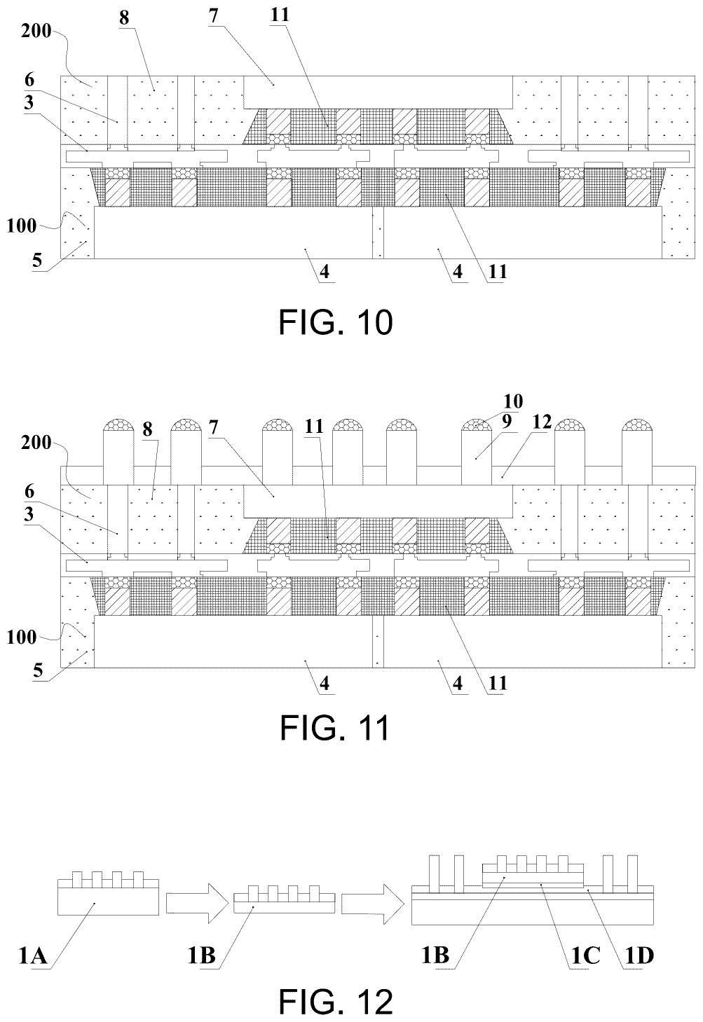

This embodiment further discloses a preparation method for a chip package structure, which includes the following steps:
S1: as shown in FIG. 1, preparing a carrier board 1, and preparing a separation layer 2 on an upper surface of the carrier board 1;
S2: as shown in FIG. 2, preparing a metal wiring layer 3 on a surface of the separation layer 2;
S3: as shown in FIG. 3, flip-chipping front surfaces of a plurality of first chips 4 on a surface of the metal wiring layer 3;
S4: as shown in FIG. 4, molding the first chip 4 to form a first package body 100, wherein the first package body 100 includes the first chip 4 and a first molding layer 5 covering the first chip 4;
S5: as shown in FIG. 5, thinning one surface that is of the first package body 100 and that is far away from the metal wiring layer 3, and simultaneously thinning the first molding layer 5 and the first chip 4;
S6: as shown in FIG. 6, removing the carrier board 1 by removing the separation layer 2;
S7: as shown in FIG. 7, turning over a combination of the first package body 100 and the metal wiring layer 3 to enable the metal wiring layer 3 to be arranged upwards, and processing a first metal pillar 6 connected to the metal wiring layer 3 on the metal wiring layer 3;
S8: as shown in FIG. 8, flip-chipping a front surface of a second chip 7 on the surface of the metal wiring layer 3;
S9: as shown in FIG. 9, molding the second chip 7 and the first metal pillar 6 to form a second package body 200, wherein the second package body 200 includes the second chip 7, the first metal pillar 6 and a second molding layer 8 covering the second chip 7 and the metal pillar;
S10: as shown in FIG. 10, thinning one surface that is of the second package body 200 and that is far away from the metal wiring layer 3, thinning the second chip 7, the first metal pillar 6 and the second molding layer 8, and exposing the first metal pillar 6 and the second chip 7; and
S11: as shown in FIG. 11, processing one surface that is of the second package body 200 and that is far away from the metal wiring layer 3 to obtain a second metal pillar 9, and processing a solder ball 10 on an end surface of the second metal pillar 9, wherein the second metal pillar 9 is at least partially connected to the corresponding first metal pillar 6.

In practice, in the step S5, only the first molding layer 5 is thinned, and the first chip 4 is not thinned.

As shown in FIG. 4, in this embodiment, the step S4, before molding the first chip 4, further includes providing a filler 11 between the front surface of the first chip 4 and the metal wiring layer 3.

As shown in FIG. 9, in this embodiment, the step S9, before molding the second chip 7 and the first metal pillar 6, further includes providing a filler 11 between the front surface of the second chip 7 and the metal wiring layer 3.

As shown in FIG. 11, in this embodiment, the step S11 further includes processing an insulation layer 12 on one surface that is of the second package body 200 and that is far away from the metal wiring layer 3, wherein the second metal pillar 9 penetrates through the insulation layer 12.

According to the chip package structure of the present disclosure, the first chip 4 and the second chip 7 are not ground before flip-chipped on the metal wiring layer 3, but ground after flip-chip and molding. This grinding can ensure that the thickness of the first chip 4 and the second chip 7 is as thin as possible without breaking, so that the thickness of the entire chip package structure is greatly reduced to meet the demand for thinness and convenience in the market. The extremely thin second chip 7 (bridge chip) can reduce the design height of the first metal pillar 6, and thus reduce the difficulty of the process of electroplating the first metal pillar 6.

In some embodiments, the grinding thickness of the first package body 100 and the second package body 200 is determined based on an actual product requirement.

In some embodiments, the first package body and the second package body are thinned by polishing and other modes.

The above mentioned contents are merely preferred embodiments of the present disclosure and are not intended to limit the patent protection scope of the present disclosure. The equivalent structure transformation made by using the contents of the specification and the drawings of the present disclosure, or direct or indirect applications to other related technical fields, are all included in the protection scope of the present disclosure.

What is claimed is:

1. A chip package structure, comprising:
a metal wiring layer, wherein the metal wiring layer is provided with a first surface and a second surface;
a plurality of first chips, wherein a front surface of each of the plurality of first chips is flip-chipped on the first surface of the metal wiring layer;
a first molding layer, wherein the first molding layer covers the plurality of first chips, and a side of the first molding layer far away from the metal wiring layer is flush with a back surface of each of the plurality of first chips;
a second chip, wherein a front surface of the second chip is flip-chipped on the second surface of the metal wiring layer;
a first metal pillar, wherein the first metal pillar is formed on the second surface of the metal wiring layer;
a second molding layer, wherein the second molding layer covers the second chip and the first metal pillar, and a side of the second molding layer far away from the metal wiring layer is flush with a back surface of the second chip and an end surface of the first metal pillar; and
a second metal pillar, wherein the second metal pillar is formed on the side of the second molding layer far away from the metal wiring layer, and the second metal pillar is at least partially connected to the corresponding first metal pillar.

2. The chip package structure according to claim 1, wherein a filler is provided between the front surface of each of the plurality of first chips and the metal wiring layer.

3. The chip package structure according to claim 1, wherein a filler is provided between the front surface of the second chip and the metal wiring layer.

4. The chip package structure according to claim 1, further comprising:
an insulation layer, wherein the insulation layer is positioned on the side of the second molding layer away from the metal wiring layer, and the second metal pillar penetrates through the insulation layer.

5. The chip package structure according to claim 4, wherein the insulation layer comprises a PI film.

6. A preparation method for a chip package structure, comprising the following steps:
S1: preparing a carrier board, and preparing a separation layer on an upper surface of the carrier board;
S2: preparing a metal wiring layer on a surface of the separation layer;
S3: flip-chipping front surfaces of a plurality of first chips on a surface of the metal wiring layer;
S4: molding the plurality of first chips to form a first package body, wherein the first package body comprises the plurality of first chips and a first molding layer covering the plurality of first chips;
S5: thinning a surface of the first package body far away from the metal wiring layer, and thinning the first molding layer or simultaneously thinning the first molding layer and the plurality of first chips;
S6: removing the carrier board by removing the separation layer;
S7: turning over a combination of the first package body and the metal wiring layer to enable the metal wiring layer to be arranged upwards, and processing a first metal pillar connected to the metal wiring layer on the metal wiring layer;
S8: flip-chipping a front surface of a second chip on the surface of the metal wiring layer;
S9: molding the second chip and the first metal pillar to form a second package body, wherein the second package body comprises the second chip, the first metal pillar and a second molding layer covering the second chip and the metal pillar;
S10: thinning a surface of the second package body far away from the metal wiring layer, thinning the second chip, the first metal pillar and the second molding layer, and exposing the first metal pillar and the second chip; and
S11: processing a surface that is of the second package body far away from the metal wiring layer to obtain a second metal pillar, and processing a solder ball on an end surface of the second metal pillar, wherein the second metal pillar is at least partially connected to the corresponding first metal pillar.

7. The preparation method for the chip package structure according to claim 6, wherein the step S4, before molding the plurality of first chips, further comprises providing a filler between the front surface of each of the plurality of first chips and the metal wiring layer.

8. The preparation method for the chip package structure according to claim 6, wherein the step S9, before molding the second chip and the first metal pillar, further comprises providing a filler between the front surface of the second chip and the metal wiring layer.

9. The preparation method for the chip package structure according to claim 6, wherein the step S11 further comprises processing an insulation layer on the surface the second package body far away from the metal wiring layer, wherein the second metal pillar penetrates through the insulation layer.

10. The preparation method for the chip package structure according to claim 9, wherein the insulation layer comprises a PI film.
